(19) United States
(12) Patent Application Publication
(10) Pub. No.: US 2024/0357765 A1
(43) Pub. Date: Oct. 24, 2024

(54) AIRFLOW OPTIMIZATION DEVICES FOR CRYPTOCURRENCY MINING, AND RELATED SYSTEMS, COMPONENTS, AND METHODS

(71) Applicant: Professional ASIC Services LLC, Sheridan, WY (US)

(72) Inventors: Rick Vanderhulst, Loveland, CO (US); Colin Crossman, Cheyenne, WY (US); Deanna Crossman, Cheyenne, WY (US); Rob Warren, Arvada, CO (US)

(21) Appl. No.: 18/638,962

(22) Filed: Apr. 18, 2024

Related U.S. Application Data
(60) Provisional application No. 63/460,420, filed on Apr. 19, 2023.

(51) Int. Cl. H05K 7/20; G06F 1/20

(52) U.S. Cl. CPC H05K 7/20172; G06F 1/20; H05K 7/20145

(57) ABSTRACT

A computing system may include at least one computing device, such as a cryptocurrency mining device, including a first device outlet configured to provide a first airflow and a second device outlet configured to provide a second airflow. The system may further include at least one airflow shroud coupled to each computing device of the at least one computing device. Each airflow shroud may include at least one airflow shroud configured to receive the first airflow from the first device outlet and the second airflow from the second device outlet, and an airflow shroud outlet configured to provide a combined airflow from the first airflow and the second airflow directed away from the at least one computing device.

### CROSS-REFERENCE TO RELATED APPLICATIONS

This application claims priority to U.S. Provisional Patent Application No. 63/460,420 filed on Apr. 19, 2023, the disclosure and content of which is incorporated by reference herein in its entirety.

### BACKGROUND

The disclosure relates to airflow cooling devices, and in particular to airflow optimization devices for cryptocurrency mining, and related systems, components, and methods.

Computing devices, such as cryptocurrency mining devices, may generate large quantities of heat under load. Over time, elevated temperatures may reduce the useful life of the computing device, and excessive or prolonged heat exposure may cause damage to certain components. Moreover, many applications, such as cryptocurrency mining arrays, may employ large numbers of already-deployed computing devices. Accordingly, there is a need for inexpensive cooling solutions that improve cooling performance and efficiency for a large number of already-deployed computing devices.

### SUMMARY

According to some embodiments, a computing system may include at least one computing device comprising a first device outlet configured to provide a first airflow and a second device outlet configured to provide a second airflow. The system may further include at least one airflow shroud coupled to each computing device of the at least one computing device, each airflow shroud comprising at least one airflow shroud inlet configured to receive the first airflow from the first device outlet and the second airflow from the second device outlet and an airflow shroud outlet configured to provide a combined airflow from the first airflow and the second airflow directed away from the at least one computing device.

According to some embodiments, an airflow shroud may include at least one airflow shroud inlet configured to receive a first airflow from a first device outlet of at least one computing device and a second airflow and so on from a second device outlet of the at least one computing device, and an airflow shroud outlet configured to provide a combined airflow from the first airflow and the second airflow away from the at least one computing device.

According to some embodiments, a method may include disposing a plurality of computing devices in an array and coupling a plurality of respective airflow shrouds to the plurality of computing devices. The method may further include, for each computing device, providing a first airflow through a first device outlet of the computing device into at least one airflow shroud inlet of the respective airflow shroud, providing a second airflow through a second device outlet of the computing device into the at least one airflow shroud inlet of the respective airflow shroud. directing the first airflow and the second airflow through the shroud to provide a combined airflow and directing the combined airflow through an airflow shroud outlet away from the respective computing device.

These and other disclosed aspects and examples may be suitably combined with each other as would be apparent to anyone of ordinary skill in the art. Additional features and advantages are disclosed in the following description and drawings, and in part will be readily apparent therefrom to those skilled in the art or recognized by practicing the disclosure as described herein.

### BRIEF DESCRIPTION OF THE DRAWINGS

Examples are described in more detail below with reference to the appended drawings.

FIGS. 1A-1E illustrate an array of cryptocurrency mining devices connected to an air barrier, according to the prior art.

FIGS. 2A-2E illustrate an array of cryptocurrency mining devices with attached exhaust shrouds connected to an air barrier, according to some embodiments.

FIGS. 3A-3D illustrate a cryptocurrency mining device with an attached exhaust shroud, according to some embodiments.

FIGS. 4A-4E illustrate additional views of the exhaust shroud of FIGS. 3A-3D, according to some embodiments.

FIG. 5 is a flowchart diagram illustrating operations for providing improved airflow for a plurality of computing devices, according to some embodiments.

FIGS. 6A-6E illustrate an alternative cryptocurrency mining device with an attached exhaust shroud, according to some embodiments.

FIGS. 7A-7E illustrate additional views of the exhaust shroud of FIGS. 6A-6E, according to some embodiments.

FIGS. 8A-8D illustrate a cryptocurrency mining device with an attached intake shroud, according to some embodiments.

FIGS. 9A-9E illustrate additional views of the intake shroud of FIGS. 8A-8D, according to some embodiments.

FIGS. 10A-10E illustrate a cryptocurrency mining device with an attached air restrictor, according to some embodiments.

FIGS. 11A-11E illustrate additional views of the air restrictor of FIGS. 10A-10D, according to some embodiments.

### DETAILED DESCRIPTION

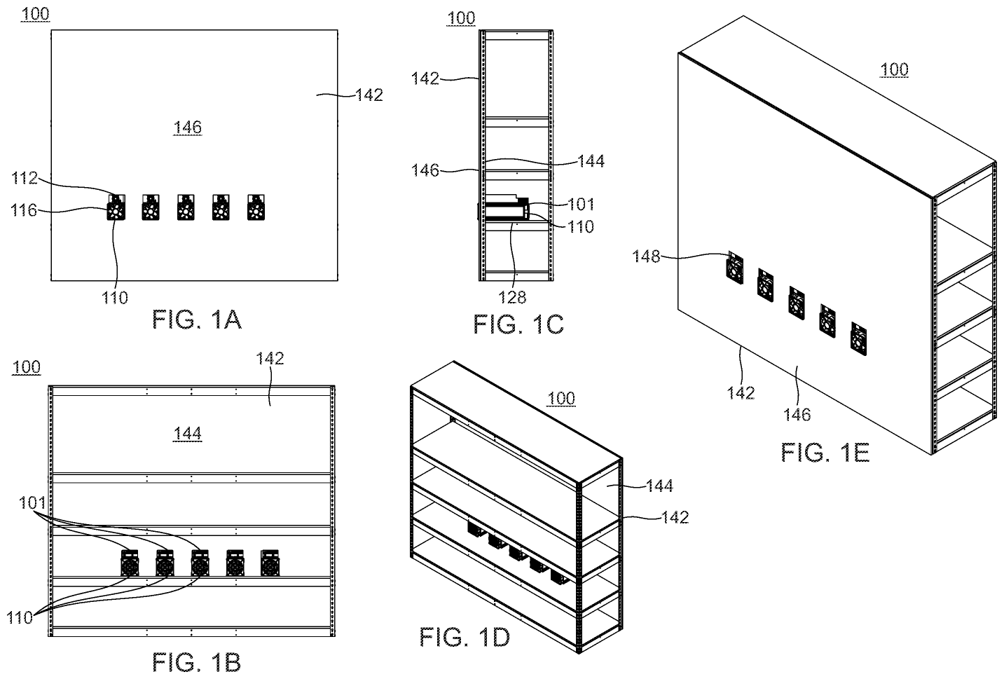

FIGS. 1A-1E illustrate a conventional system 100 including an array 101 of computing devices 110 (e.g., cryptocurrency mining devices 128) connected to an air barrier 142. Each computing device 110 is located on a device side 144 (e.g., a “cool” side) of the barrier 142 and passes cool air through the device 110 to cool an application-specific integrated circuit (“ASIC”), a power supply, and/or other components. The cooling process heats the air, and the heated air is output from a first device outlet 112 (e.g., for an ASIC ventilation passage) and a second device outlet 116 (e.g., for a power supply ventilation passage) to a ventilation side (e.g., a “hot” side) of the barrier 142 through one or more openings 148 in the barrier 142.

FIG. 1A is a view of the system 100 on the ventilation side 146 of the barrier 142. FIG. 1B is a view of the system 100 on the device side 144 of the barrier 142. FIG. 1C is a side view of the system 100. FIG. 1D is an isometric view of the system 100 on the ventilation side 146 of the barrier 142. FIG. 1E is an isometric view of the system 100 on the device side 144 of the barrier 142.

One problem with the arrangement of FIGS. 1A-1E is that many popular cryptocurrency mining devices 128 have staggered horizontally device outlets, which can result in sub-optimal airflow and cooling. In addition, many devices 128 have different airflows through different ventilation passages, which can result in pressure mismatches that may further reduce cooling performance for certain components.

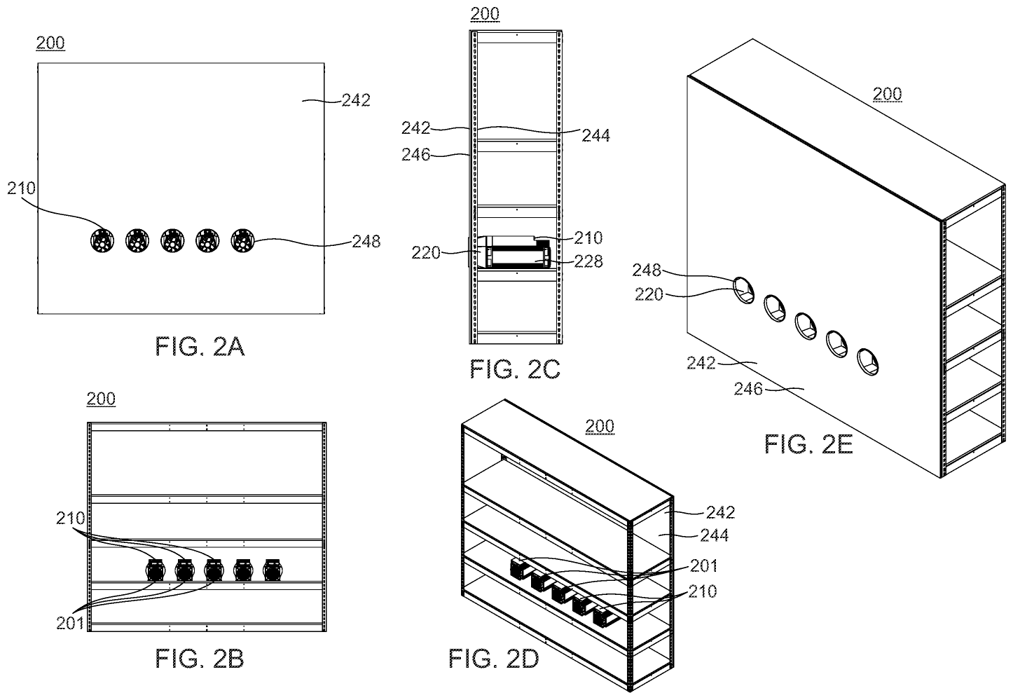

To address these and other problems, FIGS. 2A-2E illustrate a computing system 200 including an array 201 of cryptocurrency mining devices 228 with attached exhaust shrouds 220 connected to an air barrier 242, according to some embodiments.

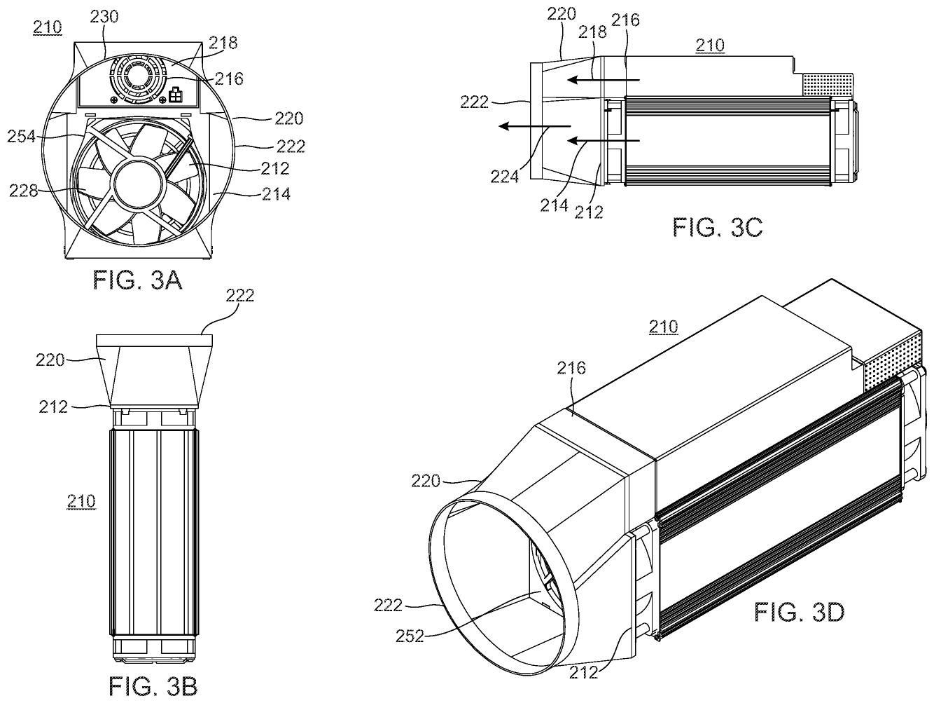

The computing system 200 is designed to efficiently manage heat generated by its components. This computing system 200 comprises at least one computing device 210 (e.g., cryptocurrency mining devices 228 in this example), each equipped with two distinct device outlets: a first device outlet 212 and a second device outlet 216. The first device outlet 212 is specifically designed to generate a first airflow 214, while the second device outlet 216 is engineered to create a second airflow 218 (as shown in greater detail in FIG. 3C.

To effectively manage the airflow produced by the computing devices 210 and ensure proper heat dissipation, the computing system 200 incorporates at least one airflow shroud 220. Each computing device 210 within the system is connected to an individual airflow shroud 220, which facilitates the efficient direction of airflow away from the computing devices.

FIGS. 2A-2C are ventilation-side, device-side, and side views of the system 200 and FIGS. 2D and 2E are respective isometric ventilation-side and isometric device-side views of the system 200.

Referring now to FIGS. 3A-3D, additional detailed views of an individual computing device 210 with an attached exhaust shroud 220 are illustrated, according to some embodiments.

Each airflow shroud 220 is equipped with at least one airflow shroud inlet 222 designed to receive both the first airflow 214 originating from the first device outlet 212 and the second airflow 218 from the second device outlet 216. Additionally, the airflow shroud comprises an airflow shroud outlet 224 configured to provide a combined airflow 226 by merging the first airflow 214 and the second airflow 218. This combined airflow 226 is directed away from the computing devices 210 to ensure effective heat management.

The disclosed computing system 200 focuses on efficient heat management by incorporating multiple device outlets and airflow shrouds, which together generate and direct combined airflows away from the computing devices 210 to maintain optimal operating temperatures.

The computing system 200 may also include a plurality, matrix, or multitude of cryptocurrency mining devices 228 or other computing devices 210. These mining devices 228 perform complex mathematical calculations for verifying and securing cryptocurrency transactions, which generates significant amounts of heat.

As discussed above, the computing devices 210 may exhibit differences in airflow rates between the first airflow 214 and the second airflow 218. In this scenario, the first airflow 214 rate is higher than the second airflow 218 rate. To generate these different airflow rates, the computing device may optionally be equipped with a first fan 230 for providing the first airflow and a second fan 232 for providing the second airflow.

In this example, the first airflow 214 passing through the first device outlet 212 causes a pressure drop near the second device outlet 216, which consequently increases the airflow rate of the second airflow 218 through the second device outlet. This pressure drop is configured to prevent the backflow of air through the second device outlet into the computing device. Without the shroud 220, e.g., in the configuration of FIGS. 1A-1E above, the higher flow rate of the first airflow 214 may cause an increase in ambient pressure proximate to the second device outlet 216, which may be overpower the second fan 232 and force heated air into the second device outlet 216, which may reduce the useful life of and/or damage the power supply or other components of the computing device 210.

The airflow shroud inlet 222 may comprise a first airflow shroud inlet 234 configured to receive the first airflow 214 and a second airflow shroud inlet 236 configured to receive the second airflow 218. The first airflow shroud inlet defines a first inlet plane 238, while the second airflow shroud inlet defines a second inlet plane 240 situated upstream of the first inlet plane. The first airflow 214 passing through the first airflow shroud inlet 234 into the airflow shroud creates a venturi effect and causes a pressure drop between the second airflow shroud inlet 236 and the first inlet plane 238. This pressure drop increases the airflow rate of the second airflow 218 through the second device outlet 216 and inhibits back-flow of air through the second device outlet 216 into the computing device 210.

The computing system 200 in this example includes an airflow barrier 242 featuring a device side 244, a ventilation side 246 opposite the device side, and at least one opening 248 through the barrier. The computing devices 210 are located on the device side of the airflow barrier, while the airflow shroud outlet 224 is further configured to direct the combined airflow 226 through least one opening to the ventilation side.

FIGS. 3A-3C illustrate front, bottom and side views of the computing device 210 and attached shroud 220.

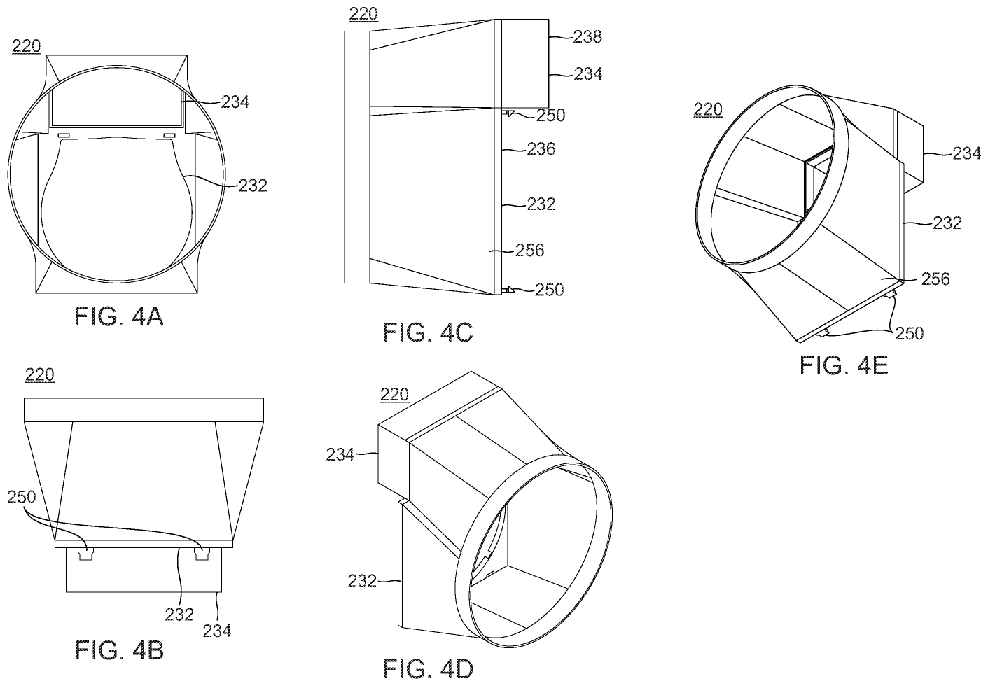

Referring now to FIGS. 4A-4E, additional views of the shroud 220 are illustrated, according to some embodiments.

In this regard, the airflow shroud 220 may include one or more attachment mechanisms, such as a plurality of clips 250 to secure the shroud 220 to the computing device 210. These clips 250 ensure the proper alignment and engagement of the at least one airflow shroud inlet 232 with the first and second device outlets 212, 216. The clips 250 can be configured to engage the housing 252 of the computing device 210 or at least one fan guard 254 placed over the first and/or second device outlets 212, 216. The clips 250 may be unitary with the body 256 of the airflow shroud, offering a seamless design. Alternatively, or in addition, tensioning devices such as spring-clips, screws, and/or adhesives can also be used for attachment.

The at least one airflow shroud inlet 222 may comprise a first airflow shroud inlet 232 configured to receive the first airflow 214 and a second airflow shroud inlet 234 designed to receive the second airflow 218. The first airflow shroud inlet 232 defines a first inlet plane 236, while the second airflow shroud inlet 234 defines a second inlet plane 238 upstream of the first inlet plane 236. The first airflow 214 passing through the first airflow shroud inlet 232 results in a pressure drop between the second airflow shroud inlet 234 and the first inlet plane 236. This pressure drop increases the airflow rate of the second airflow 218 through the second device outlet 216 and inhibits any backflow of air through the second device outlet 216 into the computing device 210.

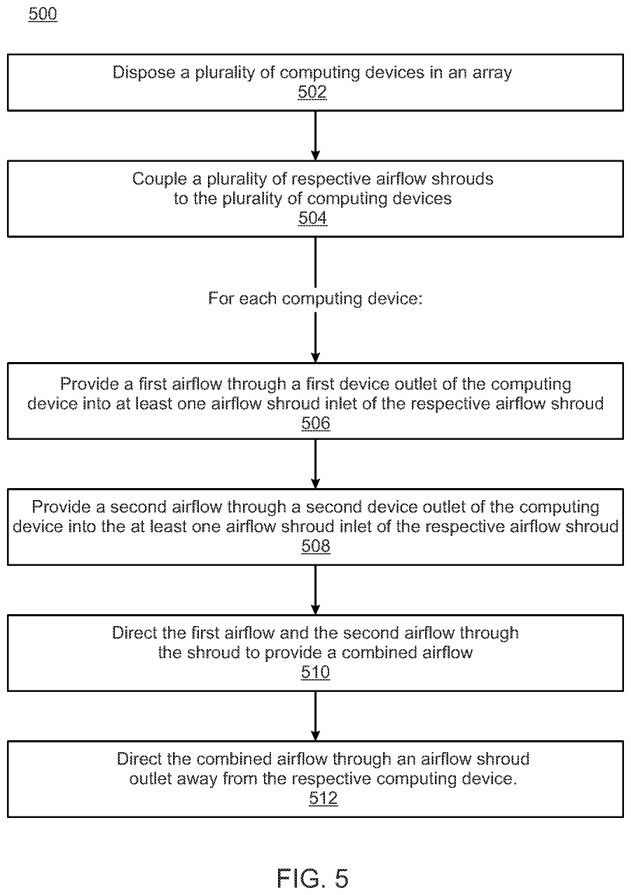

FIG. 5 is a flowchart diagram illustrating operations 500 for methods of providing improved airflow for a plurality of computing devices, according to some embodiments. The operations 500 may include arranging multiple computing devices are arranged in an array (Block 502). The operations 500 may include attaching a plurality of respective airflow shrouds to these computing devices (Block 504). For each computing device, a first airflow may be channeled through a first device outlet into at least one airflow shroud inlet of the respective airflow shroud (Block 506), and a second airflow may be channeled through a second device outlet into the at least one airflow shroud inlet of the respective airflow shroud (Block 508). The first and second airflows of each computing device may be directed through the shroud to form a combined airflow (Block 510) and may be subsequently directed through an airflow shroud outlet away from the respective computing device (Block 512).

The method can be further refined by positioning the plurality of computing devices on a device side of an airflow barrier featuring a plurality of openings, connecting each airflow shroud outlet of each respective airflow shroud to a respective opening among the plurality of openings, and directing the combined airflow from the airflow shroud outlet of the airflow shroud through the respective opening to a ventilation side of the barrier opposite the device side for each computing device.

As discussed above, an airflow barrier structure may include a hot side and a cold side, where a cryptocurrency mining device is placed on the cold side of the airflow barrier, and a shroud is attached to the mining device between the airflow barrier and the mining device. This configuration allows the mining device to maintain pneumatic communication with both sides of the barrier. In this construction, the shrouds may comprise an exhaust shroud that provides pneumatic communication to the hot side of the barrier for the mining device, and/or an intake shroud attached to the mining device.

As discussed above, computing devices may include cryptocurrency mining devices, which may employ ASICs, and which may operate on a blockchain (e.g., on the Bitcoin blockchain).

One implementation may include at least five cryptocurrency mining devices and at least five shrouds attached to the respective mining devices. In some embodiments, the exhaust flow of mining devices may converge into a common airspace within 2 meters on the hot side of the barrier.

The exhaust shrouds may include a body, a unitary attachment portion designed to mechanically attach the shroud to the cryptocurrency mining device, and a controlled flow passage ranging from 4 to 28 inches in length, intended to direct exhaust air from the device into a controlled flow. The shroud may be further configured to guide exhaust air from the device's power supply unit into the controlled flow. The shroud may be designed to block any gaps left in the mining device's construction, such as a gap between the power supply unit and the main chassis of the device, which might allow air to back-flow.

The shrouds of this disclosure may be formed using 3D printing, injection molding, or any other suitable method. The body construction of the shrouds may use materials that are compatible with the chosen construction method, as well as the thermal, mechanical, and fluidic environment in which they will be used.

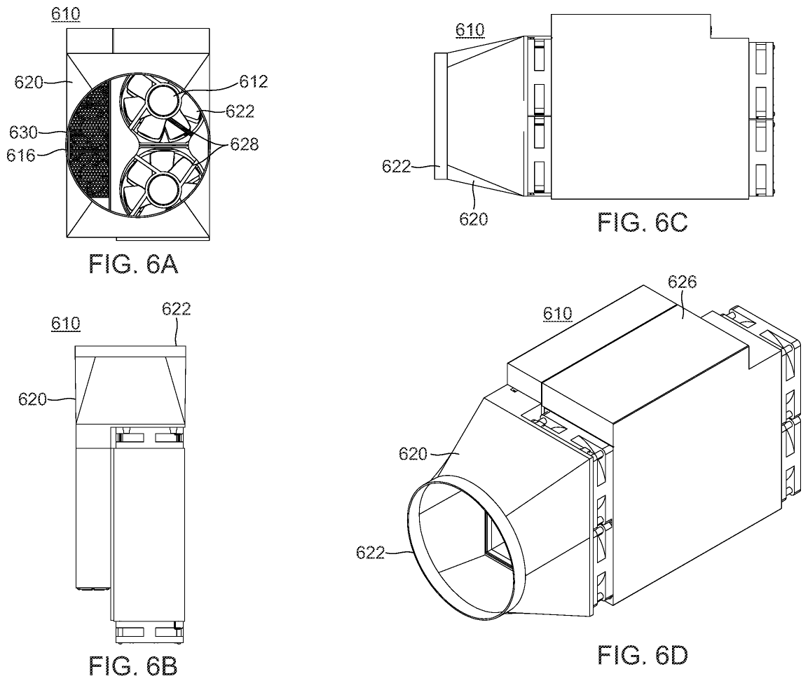

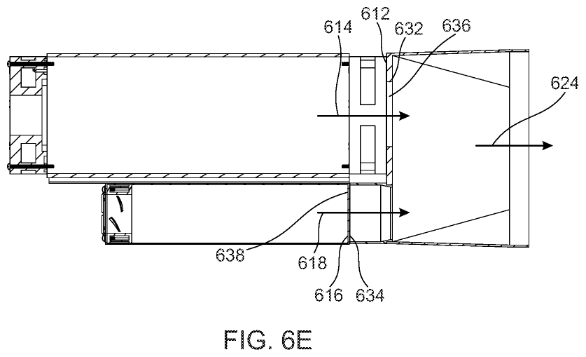

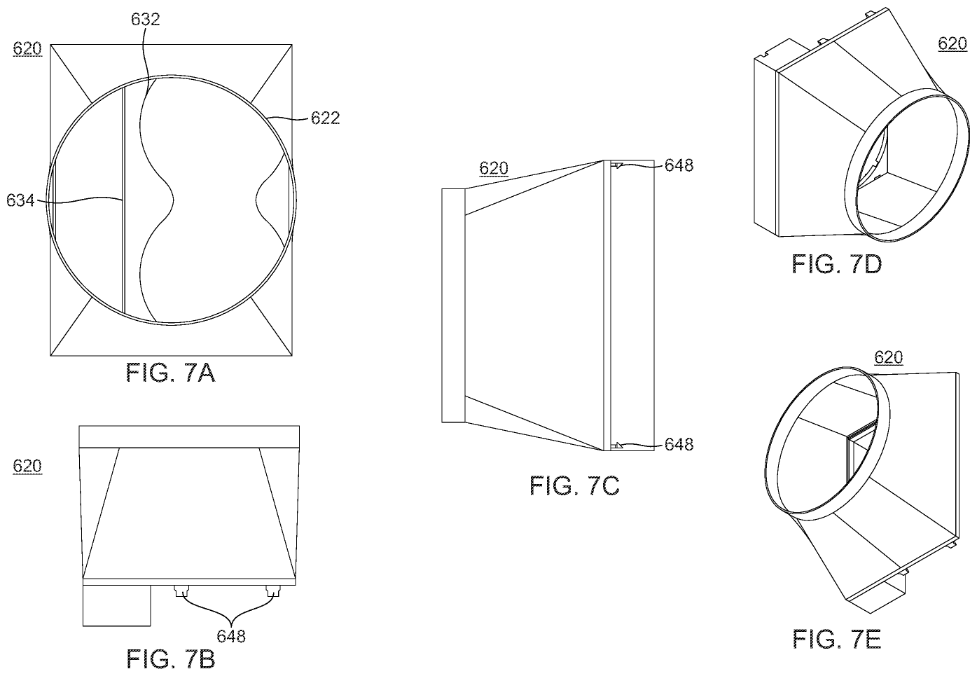

FIGS. 6A-6E illustrates an alternative computing device 610 with an attached exhaust shroud 610 is illustrated, according to some embodiments. FIGS. 7A-7E illustrate additional views of the exhaust shroud of FIGS. 6A-6E, according to some embodiments. As shown in FIGS. 6A-7E, the computing device 610 may include a pair of first device outlets 612 providing a combined first airflow 614, e.g., via first fans 628, and a second device outlet 616 providing a second airflow 618, e.g., via a second fan 630. The airflow shroud 620 may include a first airflow shroud inlet 632 for mating to the first device outlets 612 in a first inlet plane 638, a second airflow shroud inlet 634 for mating with the second device outlet 616 in a second inlet plane 640 upstream of the first inlet plane 638, and an airflow shroud outlet 622 providing a combined airflow 624, The shroud 620 may be coupled to the computing device 610 via integrated clips 650 and/or any other suitable attachment mechanism.

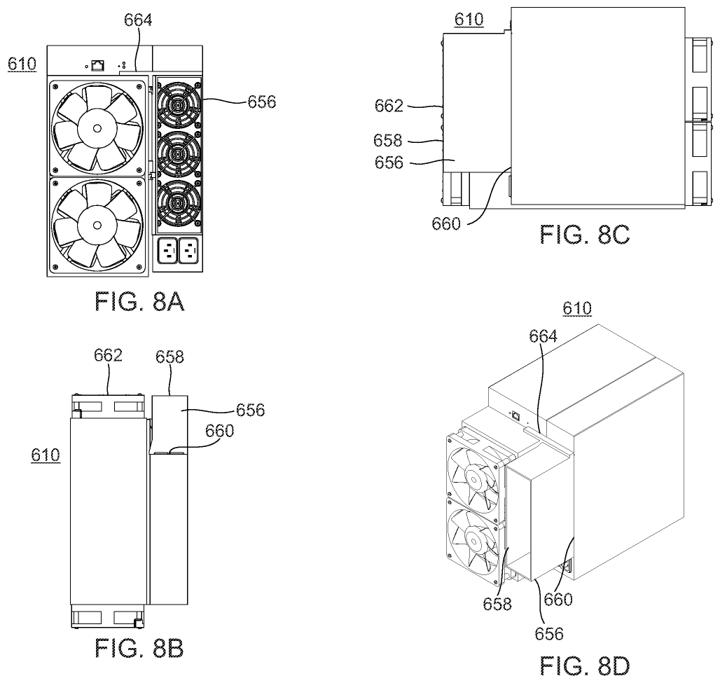

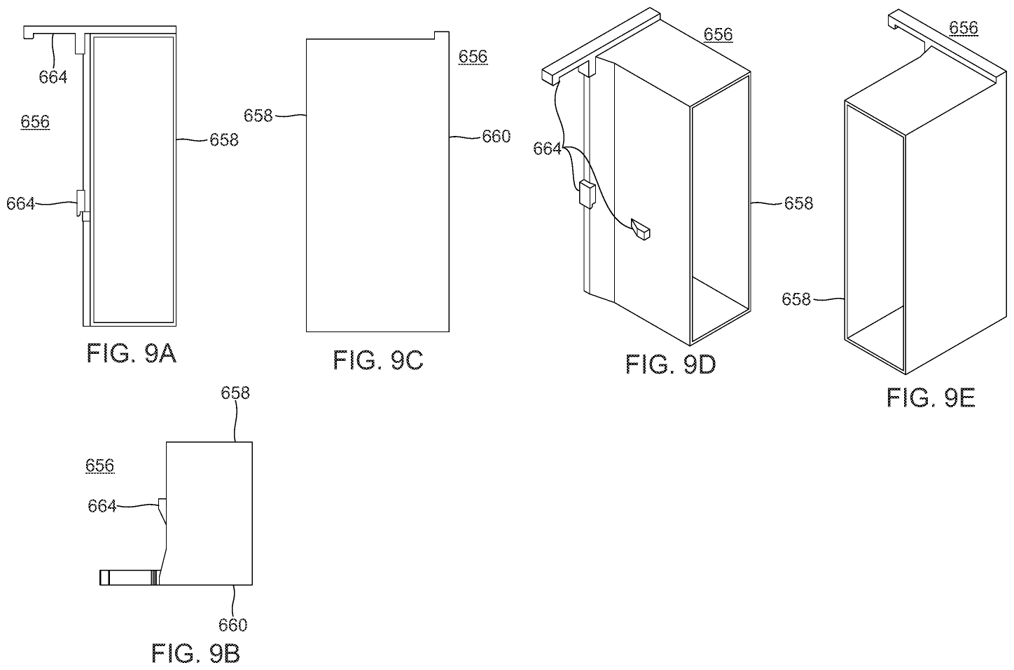

Additional components may also be provided to improve airflow through the computing device 610. In this regard, FIGS. 8A-8D illustrate the computing device 610 with an attached intake shroud 656, and FIGS. 9A-9E illustrate additional views of the intake shroud 656 of FIGS. 8A-8D, according to some embodiments. The intake shroud 656 may include an intake shroud inlet 658 and an intake shroud outlet 660 coupled to an intake of the computing device, with the intake shroud inlet 658 in line with another intake of the computing device 610. The intake shroud 656 may be coupled to the computing device 610 via one or more attachment features 664.

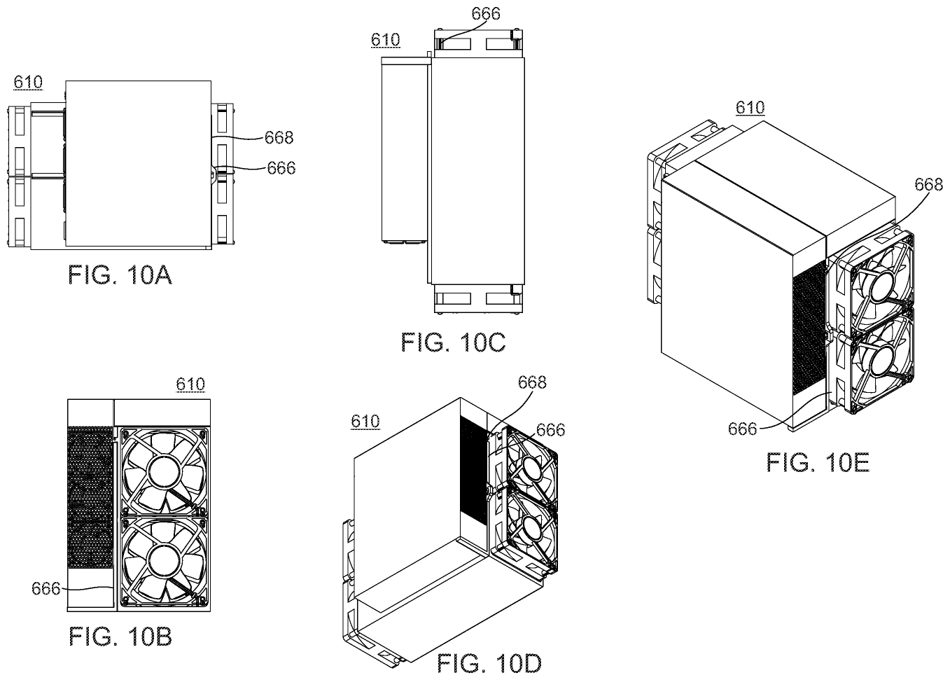

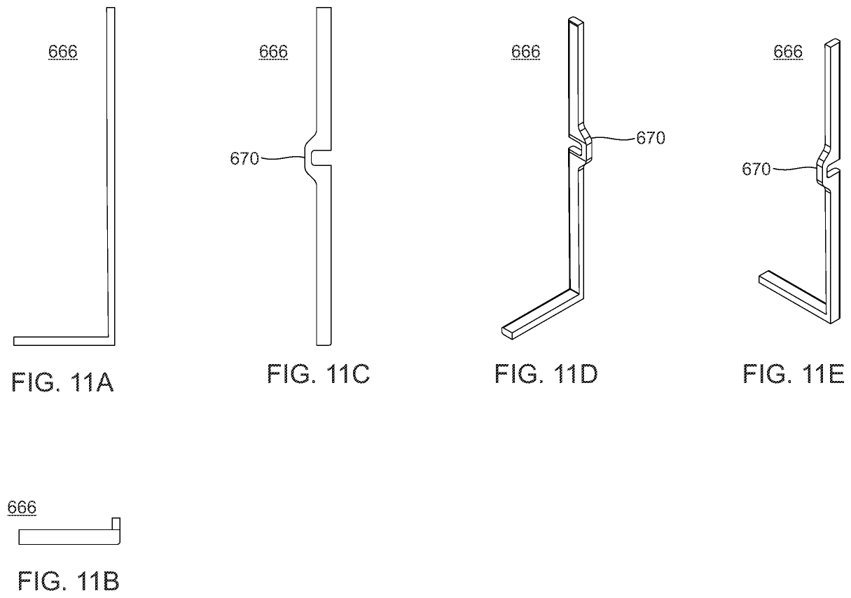

FIGS. 10A-10E illustrate the computing device 610 with an attached air restrictor 666, and FIGS. 11A-11E illustrate additional views of the air restrictor 666 of FIGS. 10A-10D, according to some embodiments. The air restrictor 666 may be designed to block a fan gap 668 or other gaps in the ventilation passages of the computing device 610 to inhibit back-flow and increase cooling efficiency. The restrictor 666 may be coupled to the computing device 610 via one or more attachment features 670.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. As used herein, the term “and/or” includes any and all combinations of one or more of the associated listed items. It will be further understood that the terms “comprises,” “comprising,” “includes,” and/or “including” when used herein specify the presence of stated features, integers, actions, steps, operations, elements, and/or components, but do not preclude the presence or addition of one or more other features, integers, actions, steps, operations, elements, components, and/or groups thereof.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element without departing from the scope of the present disclosure.

Relative terms such as “below” or “above” or “upper” or “lower” or “horizontal” or “vertical” may be used herein to describe a relationship of one element to another element as illustrated in the Figures. It will be understood that these terms and those discussed above are intended to encompass different orientations of the device in addition to the orientation depicted in the Figures. It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Unless otherwise defined, all terms including technical and scientific terms used herein have the same meaning as commonly understood by one of ordinary skill in the art to which this disclosure belongs. It will be further understood that terms used herein should be interpreted as having a meaning consistent with their meaning in the context of this specification and the relevant art and will not be interpreted in an idealized or overly formal sense unless expressly so defined herein.

It is to be understood that the present disclosure is not limited to the aspects described above and illustrated in the drawings; rather, the skilled person will recognize that many changes and modifications may be made within the scope of the present disclosure. In the drawings and specification, there have been disclosed aspects for purposes of illustration only and not for purposes of limitation.

What is claimed is:

1. A computing system comprising:
at least one computing device comprising:
a first device outlet configured to provide a first airflow; and
a second device outlet configured to provide a second airflow;
at least one airflow shroud coupled to each computing device of the at least one computing device, each airflow shroud comprising:
at least one airflow shroud inlet configured to receive the first airflow from the first device outlet and the second airflow from the second device outlet; and
an airflow shroud outlet configured to provide a combined airflow from the first airflow and the second airflow directed away from the at least one computing device.

2. The computing system of claim 1, wherein the at least one computing device comprises a plurality of cryptocurrency mining devices.

3. The computing system of claim 2, wherein a first airflow rate of the first airflow is higher than a second airflow rate of the second airflow.

4. The computing system of claim 3, wherein the at least one computing device comprises:
a first fan configured to provide the first airflow; and
a second fan configured to provide the second airflow.

5. The system of claim 2, wherein the first airflow through the first device outlet causes a pressure drop proximate the second device outlet to increase an airflow rate of the second airflow through the second device outlet.

6. The system of claim 5, wherein the pressure drop is configured to inhibit a backflow of air through the second device outlet into the computing device.

7. The system of claim 2, wherein the at least one airflow shroud inlet comprises:
a first airflow shroud inlet configured to receive the first airflow; and
a second airflow shroud inlet configured to receive the second airflow.

8. The system of claim 7, wherein the first airflow shroud inlet defines a first inlet plane, and
wherein the second airflow shroud inlet defines a second inlet plane upstream of the first inlet plane.

9. The system of claim 8, wherein the first airflow through the first airflow shroud inlet causes a pressure drop between the second airflow shroud inlet and the first plane to increase an airflow rate of the second airflow through the second device outlet and to inhibit a backflow of air through the second device outlet into the computing device.

10. The system of claim 2, further comprising an airflow barrier comprising a device side, a ventilation side 246 opposite the device side, and at least one opening therethrough,
wherein the at least one computing device is disposed on the device side of the airflow barrier, and
wherein the airflow shroud outlet is further configured to provide the combined airflow through the at least one opening to the ventilation side.

11. An airflow shroud comprising:
at least one airflow shroud inlet configured to receive a first airflow from a first device outlet of at least one computing device and a second airflow and so on from a second device outlet of the at least one computing device; and
an airflow shroud outlet configured to provide a combined airflow from the first airflow and the second airflow away from the at least one computing device.

12. The airflow shroud of claim 11, further comprising a plurality of clips 250 configured to secure the airflow shroud to the at least one computing device to matingly engage the at least one airflow shroud inlet to the first device outlet and the second device outlet.

13. The airflow shroud of claim 12, wherein the plurality of clips are configured to engage a housing 252 of the at least one computing device.

14. The airflow shroud of claim 12, wherein the plurality of clips are configured to engage at least one fan guard 254 disposed over the first device outlet and the second device outlet.

15. The airflow shroud of claim 12, wherein the plurality of clips are unitary with a body 256 of the airflow shroud.

16. The airflow shroud of claim 11, further configured to receive the first airflow such that a pressure proximate the second device outlet drops to increase an airflow rate of the second airflow through the second device outlet.

17. The airflow shroud of claim 16, wherein the pressure drop is configured to inhibit a backflow of air through the second device outlet into the computing device.

18. The airflow shroud of claim 11, wherein the at least one airflow shroud inlet comprises:
a first airflow shroud inlet configured to receive the first airflow; and
a second airflow shroud inlet configured to receive the second airflow.

19. The airflow shroud of claim 18, wherein the first airflow shroud inlet defines a first inlet plane, and
wherein the second airflow shroud inlet defines a second inlet plane upstream of the first inlet plane.

20. A method comprising:
disposing a plurality of computing devices in an array;
coupling a plurality of respective airflow shrouds to the plurality of computing devices 304;
for each computing device:
providing a first airflow through a first device outlet of the computing device into at least one airflow shroud inlet of the respective airflow shroud;
providing a second airflow through a second device outlet of the computing device into the at least one airflow shroud inlet of the respective airflow shroud;
directing the first airflow and the second airflow through the shroud to provide a combined airflow; and
directing the combined airflow through an airflow shroud outlet away from the respective computing device.
